(19) United States
(12) Patent Application Publication
(10) Pub. No.: US 2008/0311509 A1
(43) Pub. Date: Dec. 18, 2008

(54) Photopolymer Printing Plate Precursor

(75) Inventors: Alexander Williamson, Mortsel (BE); Marc Van Damme, Bonheiden (BE); Wojciech Jaunky, Wesel (DE); Hubertus Van Aert, Pulderbos (BE)

Correspondence Address: AGFA;c/o KEATING & BENNETT, LLP, 1800 Alexander Bell Drive, SUITE 200, Reston, VA, 20191, US

(73) Assignee: AGFA GRAPHICS NV, Mortsel (BE)

(21) Appl. No.: 12/064,466

(22) PCT Filed: Aug. 18, 2006
(86) PCT No.: PCT/EP2006/065436

§ 371 Date: Feb. 22, 2008

Related U.S. Application Data
(60) Provisional application No. 60/714,751, filed on Sep. 7, 2005.

(30) Foreign Application Priority Data
Aug. 26, 2005 (EP) 05107827.7

(51) Int. Cl. G03F 7/00; G03F 7/20

(52) U.S. Cl. 430/273.1; 430/270.1; 430/286.1; 430/302

(57) ABSTRACT

A photopolymer printing plate precursor includes a photosensitive coating on a support, wherein the photosensitive coating includes a composition that is photopolymerizable upon absorption of light, and the composition includes at least one binder, a polymerizable compound, a sensitizer, and a photoinitiator. The binder is a copolymer that has a Tg of less than 70° C., and wherein 1 mol-% to 50 mol-% of the monomeric units of the copolymer are substituted by at least one acidic group, has a very high sensitivity and resistance of the exposed image portions against alkaline developers, when exposed with a laser, even if no pre-heat step is performed.

### CROSS-REFERENCE TO RELATED APPLICATIONS

This application is a 371 of PCT/EP2006/065436, filed Aug. 18, 2006. This application claims the benefit of U.S. Provisional Application No. 60/714,751, filed Sep. 7, 2005, which is incorporated by reference herein in its entirety. In addition, this application claims the benefit of European Application No. 05107827.7, filed Aug. 26, 2005, which is also incorporated by reference herein in its entirety.

### BACKGROUND OF THE INVENTION

1. Field of the Invention

The present invention relates to a photopolymer printing plate precursor including a photosensitive coating on a support, wherein the photosensitive coating includes a composition that is photopolymerizable upon absorption of light, and the composition includes a binder, a polymerizable compound, a sensitizer, and a photoinitiator.

The present invention also relates to a method of making a lithographic printing plate with the photopolymer printing plate precursor.

2. Description of the Related Art

In lithographic printing, a so-called printing master such as a printing plate is mounted on a cylinder of the printing press. The master carries a lithographic image on its surface and a printed copy is obtained by applying ink to the image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e., ink-accepting, water-repelling) areas as well as hydrophilic (or oleophobic, i.e., water-accepting, ink-repelling) areas. In so-called “driographic” printing, the lithographic image consists of ink-accepting and ink-abhesive (ink-repelling) areas and during driographic printing, only ink is supplied to the master. The lithographic image usually is made by exposing an image to a photopolymerizable composition coated on a support and developing the image. Such photopolymerizable compositions are well known in the art and are not only used for printing plate precursors, but also, e.g., as photoresists for printed electronic circuits.

The photosensitive compositions usually include a polymeric binder, an unsaturated polymerizable compound, and a photoinitiator and often are of low sensitivity so that exposure has to be done by continuous high intensity lamps for seconds up to minutes.

As an example, such photopolymerizable compositions of low sensitivity are known from DE 2 064 080 OS, wherein the binder polymer includes specific methacrylic acid/long chain alkyl methacrylic acid ester copolymers, that preferably have an acid number from 100 to 250. Such compositions are disclosed as enhancing adhesion to metal supports of any kind, in particular to copper surfaces, and hardened layers including such copolymers are described as having a good resistance against developers.

The photosensitive resin composition according to EP 398 325 A includes as a binder a mixture of a hydrophobic polymer and a hydrophilic polymer, wherein the hydrophilic polymer includes hydrophilic groups like carboxy groups and the hydrophobic polymer preferably includes chlorine substituents and has a glass transition temperature (Tg) not higher than 5° C. The compositions are disclosed as being useful for the production of flexographic printing plates with good ink resistance.

According to U.S. Pat. No. 4,780,393 and U.S. Pat. No. 4,940,647, the photopolymerizable compositions disclosed therein, including a polymeric binder, a polymerizable compound, a photoinitiator, and a leuco dye, have advantages, e.g., in sensitivity and contrast. In Example 1, dry resist films are demonstrated in every case and exposure is done by means of an iron doped 5 kW halide lamp at a short distance.

A photopolymerizable composition including a specific photoinitiator system and optionally a polymeric binder is disclosed in GB 1 576 217 as having good light-sensitivity in combination with a high cross-linking density. According to the examples, exposure has to be done with high-energy lamps, e.g., an 8 kW “Xenokop” spot arc lamp, for a coated copper circuit plate.

Photosensitive compositions with binder copolymers including specific polymeric block units are known, e.g., from EP 718 695 A to result in a granular copolymer; from U.S. Pat. No. 5,348,844, wherein a linear block copolymer of specific composition is mixed with a latex copolymer to give a water developable composition; from U.S. Pat. No. 5,212,049 in combination with a specific polymerizable compound; from EP 480 335 A to result in amphiphilic elastomeric binders; from U.S. Pat. No. 4,248,960, wherein the copolymer is placed in a separate lamina; from U.S. for specific tercopolymer binders; from U.S. Pat. No. 6,017,678 for binder polymers with at least 4 different blocks; and from U.S. Pat. No. 6,780,566 for compositions including a mixture of specific copolymers.

Printing masters can, e.g., be obtained by the so-called computer-to-film (CtF) method, wherein various pre-press steps such as typeface selection, scanning, color separation, screening, trapping, layout, and imposition are accomplished digitally and each color selection is transferred to graphic arts film using an image-setter. After processing, the film can be used as a mask for the exposure of an imaging material called a plate precursor, and after plate processing a printing plate is obtained which can be used as a master.

Since about 1995, the so-called ‘computer-to-plate’ (CtP) method has gained a lot of interest. This method, also called ‘direct-to-plate’, bypasses the creation of film because the digital document is transferred directly to a printing plate precursor by means of a so-called plate-setter. A printing plate precursor for CtP is often called a digital plate.

To allow the direct output of digital images to printing plate precursors, there have been developed photopolymerizable compositions that are sensitive enough to be directly exposed with a laser beam and therefore short pixel times. Pixel time in the context of the present invention means the effective time each portion of the printing plate is exposed by the scanning laser beam.

Digital plates can roughly be divided into three categories: (i) silver plates, which work according to the silver salt diffusion transfer mechanism; (ii) UV/VIS photopolymer plates which contain a photopolymerizable composition that hardens upon exposure to light; and (iii) thermal (including IR photopolymer, Novolak, and latex-based) plates of which the imaging mechanism is triggered by heat or by light-to-heat conversion. Thermal plates are mainly sensitized for infrared lasers emitting at 830 nm or 1064 nm. Typical photopolymer plates are sensitized for visible light, mainly for exposure by an Ar laser (488 nm) or a FD-YAG laser (532 nm). The wide-scale availability of low cost blue or violet laser diodes, originally developed for data storage by DVD, has enabled the production of plate-setters operating at shorter wavelengths. More specifically, semiconductor lasers emitting from 350 nm to 450 nm have been realized using an InGaN material.

EP 1 403 043 discloses IR sensitive layers including a polyacrylic acid ester or polyacrylic acid amide binder having at least one free carboxylic acid group in each repeating unit. The binder is disclosed to be a homopolymer or a copolymer and preferably has a Tg from 70° C. to 300° C. Similar binders are also disclosed in EP 1 403 042, EP 1 403 041, and EP 1 176 467.

EP 1 349 006 discloses photopolymerizable compositions with high sensitivity for UV, violet, and blue light, that include specific sensitizers, and wherein the binder used in the examples is a methacrylate/methacrylic acid copolymer having a Tg of over 100° C.

In known photopolymer plates, in particular in plates of high sensitivity, it has been observed that the process of polymerization during exposure often comes to an end before all of the exposed areas have enough resistance to not be dissolved by an aqueous developer. It has been found that this point, where little or no further polymerization occurs, can be overcome by a so called pre-heat step. The pre-heat step usually is done directly after light exposure, in particular when using visible or UV lasers, and typically consists of heating the printing plate precursor for 10 seconds to 1 minute to temperatures in the range of 90° C. to 150° C. to promote polymerization before the development step. This step is unfavorable as it requires special equipment and extra time for the manufacturing process. In addition the pre-heat step may cause artifacts in the printed image like so-called asteroids that are prevented by the preferred embodiments of the present invention, as described below.

### SUMMARY OF THE INVENTION

In order to overcome the problems described above, preferred embodiments of the present invention provide a photopolymer printing plate precursor that can be exposed by a low intensity laser, and that has sufficient resistance of the imagewise hardened composition, even if no pre-heat step is performed between exposure and development, and that can be processed by alkaline developers without loosening portions of the image.

Surprisingly, advantages of a preferred embodiment of the present invention are achieved by a photopolymer printing plate precursor having a photopolymerizable composition including at least one binder, a polymerizable compound, a sensitizer, and a photoinitiator, wherein the binder is a copolymer that has a Tg of less than 70° C. and wherein 1 mol-% to 50 mol-% of the monomeric units of the copolymer contain at least one acidic group. The printing plate precursor according to various preferred embodiments of the present invention is a flexographic or lithographic printing plate precursor, the latter being highly preferred.

In particular, advantages of another preferred embodiment of the present invention can be achieved by a method of making a lithographic printing plate including the steps of providing a photopolymer printing plate precursor as described above, exposing the printing plate precursor with a laser, and processing the printing plate precursor in an aqueous alkaline developer.

Further preferred embodiments of the printing plate precursor and of the method of making a lithographic printing plate therewith are set forth below.

Other features, elements, steps, characteristics and advantages of the present invention will become more apparent from the following detailed description of preferred embodiments thereof.

### DETAILED DESCRIPTION OF PREFERRED EMBODIMENTS

A preferred embodiment of the present invention relates to a photopolymer printing plate precursor including a photosensitive coating on a support, wherein the photosensitive coating includes a composition that is photopolymerizable upon absorption of light, the composition includes at least one binder, a polymerizable compound, a sensitizer, and a photoinitiator, wherein the binder is a copolymer that has a Tg of less than 70° C. and 1 mol-% to 50 mol-% of the monomeric units of the copolymer contain at least one acidic group.

The glass transition temperature (Tg) according to a preferred embodiment of the present invention is preferably determined by differential scanning calorimetry (DSC).

Although the photopolymer printing plate precursor can also advantageously be used for high-intensity exposure and also when using a pre-heat step, the advantages of the various preferred embodiments of the present invention are particularly pronounced for laser exposure with medium to low energy and no pre-heat step, in particular when using UV or visible light.

Not knowing the underlying mechanism, the low Tg binder results in a lower overall Tg for the photolayer, which might allow easier diffusion of the initiating species and the propagating monomers through the photopolymerizing matrix, which results in a greater degree of polymerization without the need to pre-heat to raise the temperature of the photolayer above the Tg. Possibly because irradiation with a visible laser produces little heat, the advantage of a low Tg binder may be more pronounced for visible light-sensitive systems than for IR sensitive systems in which heat is produced during irradiation.

In a preferred embodiment of the present invention, the photopolymerizable composition is preferably sensitive to wavelengths between 300 nm and 1200 nm, in particular between 300 nm and 600 nm, and particularly preferred between 350 nm and 450 nm. It is preferred that the photopolymerizable composition has a high sensitivity, in particular, that the minimum exposure necessary for image formation measured on the surface of the plate is 100 PJ/cm² or less.

The binder of a preferred embodiment of the present invention can be selected from a wide series of organic copolymers. The copolymer can be polymerized from two, three, four, or more different mixed monomers and preferably contains two or three different monomers. In the context of the present invention, different monomers means monomers of different chemical structure. The different monomers can be distributed in the binder copolymer in any way, e.g., randomly or as blocks. In a preferred embodiment of the present invention, the different monomers are distributed randomly and/or include blocks with an average length of less than 20 monomeric units, for example.

The binder can also be a composition of different copolymers, as long as the average Tg of the composition is less than 70° C. and 1 mol-% to 50 mol-% of the monomeric units in the composition contain at least one acidic group.

The Tg of the binder preferably is less than 60° C., in particular less than 50° C., and particularly preferred less than 30° C. However, this value is dependent on the amount of binder used in the photolayer. For example, when a larger amount of binder is used, it becomes more important that the Tg is low than when a lower amount of binder is used, due to the fact that a small amount of binder will have less influence on the overall Tg of the photolayer than a large amount of binder. The amount of binder(s) generally ranges from 10% to 90% by weight, preferably 20% to 80% by weight, relative to the total weight of the non-volatile components of the composition.

In a preferred embodiment of the present invention, from 2 mol-% to 30 mol-%, and particularly preferred from 5 mol-% to 25 mol-% of the monomeric units of the copolymer contain at least one acidic group.

The acidic group is preferably a carboxylic acid group (—COOH), a carboxylic anhydride group (—(CO)O(CO)—), a sulfo group (—SO₃H), an imido group (HN═), a phosphono group (—PO(OH)₂), an N-acyl sulfonamido group (—SO₂NH—COR), or a phenolic hydroxy group (-phenyl-OH).

Particularly preferred binders are copolymers including carboxylic acid groups as the acidic group, in particular copolymers containing monomeric units of α,β-unsaturated carboxylic acids and/or monomeric units of α,β-unsaturated dicarboxylic acids, preferably acrylic acid, methacrylic acid, crotonic acid, maleic acid, or itaconic acid.

Particular useful examples of copolymers are those containing units of (meth)acrylic acid, itaconic acid and/or crotonic acid together with units of alkyl(meth)acrylates, substituted alkyl(meth)acrylates (such as hydroxyethylmethacrylate), fluoroalkyl(meth)acrylates, allyl (meth)acrylates, and/or (meth)acrylonitrile. Also suitable are copolymers containing units of maleic anhydride, maleic acid or maleic acid monoalkyl, and alkyleneoxy or aminoalkyleneoxy esters. Among those are, for example, copolymers containing units of maleic anhydride and styrene, unsaturated ethers or esters or unsaturated aliphatic hydrocarbons, and the esterification products obtained from such copolymers.

Further suitable binders are products obtainable from the reaction of hydroxyl-containing polymers with intramolecular dicarboxylic anhydrides, such as maleic anhydride or (meth)acrylic anhydride. Further useful binders are polymers in which groups with acidic hydrogen atoms are present, which have been modified by reaction of —CO₂H, —OH, or —NH₂ groups with, for example isocyanate, hydroxy, carboxy, or epoxy group containing compounds. Also suitable are polymers with aliphatic or aromatic hydroxyl groups, for example copolymers containing units of hydroxyalkyl(meth)acrylates, allyl alcohol, hydroxystyrene or vinyl alcohol, as well as epoxy resins, provided they carry a sufficient number of free OH groups.

The organic polymers used as binders have a typical mean molecular weight M_{w} between 600 and 2,000,000, preferably between 1,000 and 500,000. Preference is further given to polymers having an acid number between 10 to 250, preferably 20 to 200, or a hydroxyl number between 50 and 750, preferably between 100 and 500.

In a preferred embodiment of the present invention, the photopolymerizable composition includes a radical stabilizer. The radical stabilizer can be selected from known radical stabilizers. Compounds useful as radical stabilizers are also known as antioxidants or radical scavengers that are used as additives for, e.g., polymers. Preferably the radical stabilizer is a compound selected from the group consisting of phenoles, organic phosphites, organic phosphonites, amines, hydroxylamines, lactones, hydrochinones, divalent sulfur compounds like thioethers and thioesters, metal complexants, wherein phenoles include mono-, di-, and trihydroxyphenyl compounds, and in particular the radical stabilizer is a compound selected from the group consisting of hindered phenoles, O-alkylated hydrochinones, organic phosphites, organic phosphonites, aromatic amines, hindered amines, dialkyl hydroxylamines, benzofuranones, and dialkyl thiodipropionates.

The radical stabilizers are preferably incorporated in the photopolymerizable composition in an amount of 0.01 wt. % to 5 wt. %, in particular from 0.015 wt. % to 3 wt. %, with respect to the total weight of the non-volatile compounds of the photopolymerizable composition.

A preferred sensitizing dye (sensitizer), when incorporated in the photopolymerizable composition, has an absorption wavelength ranging from 300 nm to 1200 nm, preferably from 300 nm to 600 nm, and particularly preferred from 350 nm to 450 nm, and makes the photopolymer printing plate sensitive to light within these wavelength ranges.

In a preferred embodiment of the present invention, a sensitizer having a solubility in methyl ethyl ketone of at least 15 g/kg, preferably from 15 to 250 g/kg, measured at 20° C. is preferably used.

Known sensitizing dyes can be used in the composition. Suitable classes include dialkylaminobenzene compounds like (Ia) and (Ib)

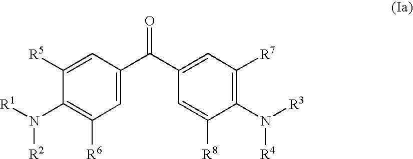

wherein each of R¹ to R⁴, which are independent of one another, is an alkyl group having 1 to 6 carbon atoms (C₁₋₆ alkyl group), and each of R⁵ to R⁸ is a hydrogen atom or a C₁₋₆ alkyl group, provided that R¹ and R², R³ and R⁴, R¹ and R⁵, R² and R⁶, R³ and R⁷, or R⁴ and R⁸, may be bonded to each other to form a ring;

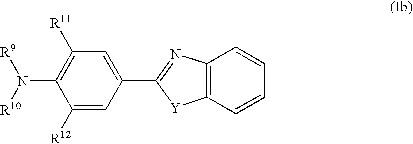

wherein each of R⁹ and R¹⁰, which are independent of each other, is a C₁₋₆ alkyl group, each of R¹¹ and R¹², which are independent of each other, is a hydrogen atom or a C₁₋₆ alkyl group, Y is a sulfur atom, an oxygen atom, dialkylmethylene or —N(R¹³)—, and R¹³ is a hydrogen atom or a C₁₋₆ alkyl group, provided that R⁹ and R¹⁰, R⁹ and R¹¹, or R¹⁰ and R¹², may be bonded to each other to form a ring, as disclosed in EP 1 148 387 A1; compounds according to formula (II)

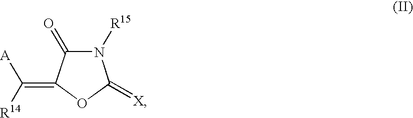

wherein A represents an optionally substituted aromatic ring or heterocyclclic ring, X represents an oxygen atom, a sulfur atom, or

—N(R¹⁶)—, R¹⁴, R¹⁵ and R¹⁶ each independently represent a hydrogen atom or a monovalent nonmetallic atom group and A and R¹⁴, or R¹⁵ and R¹⁶ can be linked together to form an aliphatic or an aromatic ring, as disclosed in EP 1 280 006 A2; 1,3-dihydro-1-oxo-2H-indene compounds as disclosed in EP 1 035 435 A2; the sensitizing dyes disclosed in EP 1 048 982 A1, EP 985 683 A1, EP 1 070 990 A1, and EP 1 091 247 A2; and/or an optical brightening agent.

To achieve a very high sensitivity, an optical brightening agent as a sensitizer is preferred. A typical optical brightener, also known as “fluorescent whitening agent”, is a colorless to weakly colored organic compound that is capable of absorbing light having a wavelength in the range from 300 nm to 450 nm and of emitting the absorbed energy as fluorescent light having a wavelength in the range between 400 nm and 500 nm. A description of the physical principle and the chemistry of optical brighteners is given in Ullmann's Encyclopedia of Industrial Chemistry, Sixth Edition, Electronic Release, Wiley-VCH 1998. Basically, suitable optical brighteners contain π-electron systems including a carbocyclic or a heterocyclic nucleus. Suitable representatives of these compounds are, e.g., stilbenes, distyrylbenzenes, distyrylbiphenyls, divinylstilbenes, triazinylaminostilbenes, stilbenzyltriazoles, stilbenzylnaphthotriazoles, bis-triazolstilbenes, benzoxazoles, bisphenylbenzoxazoles, stilbenzylbenzoxazoles, bis-benzoxazoles, furans, benzofurans, bis-benzimidazoles, diphenylpyrazolines, diphenyloxadiazoles, coumarins, naphthalimides, xanthenes, carbostyrils, pyrenes and 1,3,5-triazinyl-derivatives, and divinylfluorene compounds.

More specifically, optical brightening agents having a structure according to one of the following formulae are suitable as a sensitizer for use in the composition:

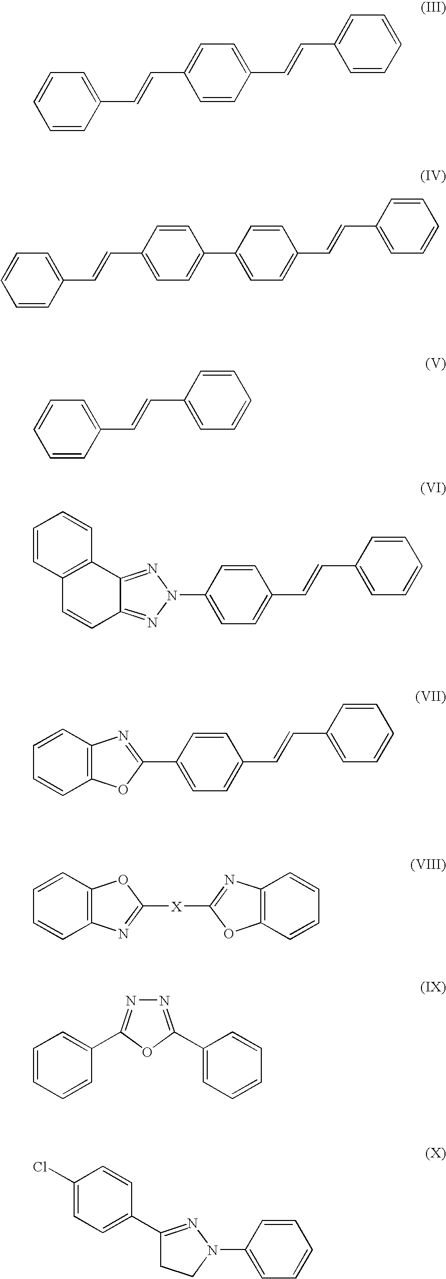

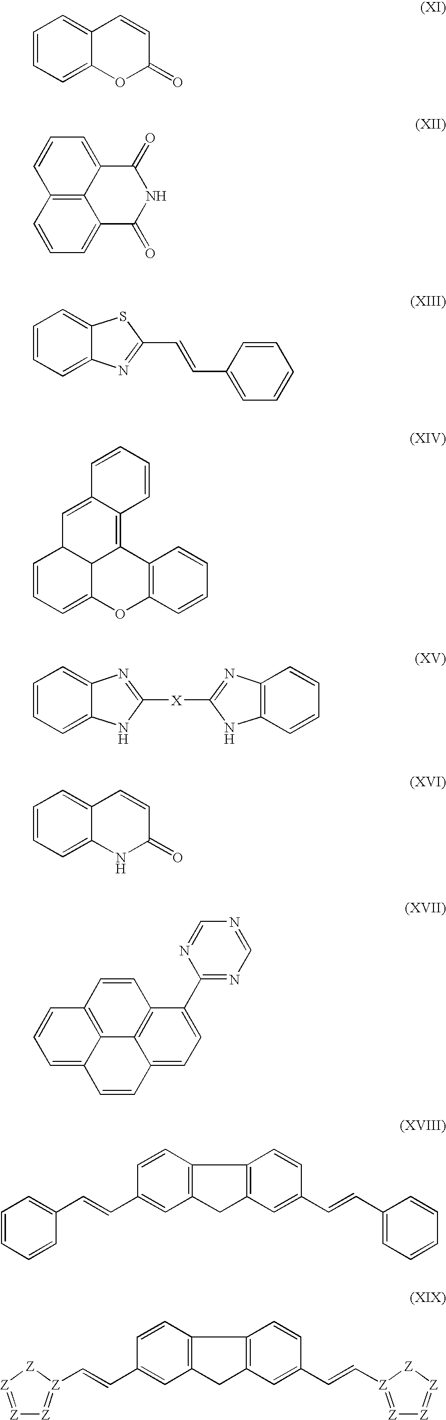

wherein Z mutually independently means non-hydrogen, non-metallic atoms; wherein X is one of the following groups, * denoting the position of attachment in the above formulae:

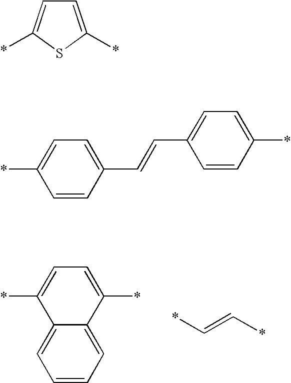

and wherein one or more of the nuclei in each of the above formulae (III) to (XIX) may be independently substituted by one or more groups selected from alkyl, alkoxy, alkylcarbonyl, alkoxycarbonyl, acyloxy, carboxyl, nitrile, amino, hydroxyl, alkylsulfonyl, and aminosulfonyl.

Especially suitable optical brighteners are compounds which are able to be dissolved in organic solvents. The optical brighteners can be used as a single compound or as a mixture of several materials. The overall amount of these compounds range from 0.1% to 10% by weight, preferably 0.5% to 8% by weight with respect to the total weight of the non-volatile compounds in the photopolymerizable composition.

Highly preferred optical brighteners include compounds of formula (III-A) to (XII-A) and (XIV-A) to (XVII-A):

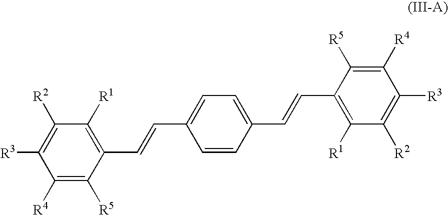

wherein
a) R¹ represents methyl, and R₂ to R₅ each represent H,
b) R² to R⁴ represent methoxy, and R¹ and R⁵ represent H,
c) R¹ represents CN, and R² to R⁵ each represent H, or
d) R³ represents CN, and R¹, R², R⁴, and R⁵ each represent H;

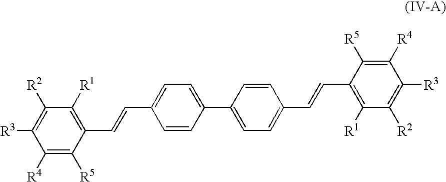

wherein R¹ to R⁴ each represent H, and R⁵ represents methoxy;

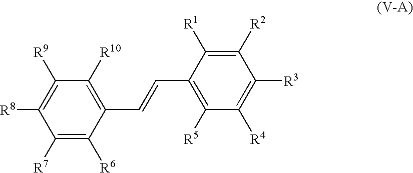

wherein
a) R¹ to R¹⁰ each represent H,
b) R¹, R², and R⁴ to R¹⁰ each represent H, and R³ represents methoxy, or
c) R¹, R², R⁴ to R⁷, and R⁹ and R¹⁰ each represent H, and R³ and R⁸ each represent methoxy;

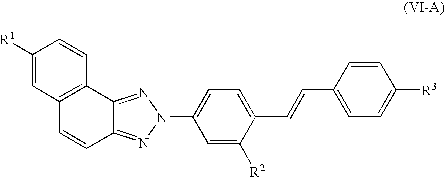

wherein
a) R¹ and R³ represent H, and R² represents phenylsulfonic acid or phenylsulfonic acid salts, or
b) R¹ represents H, R² represents CN, and R³ represents Cl;

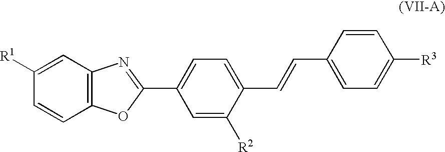

wherein
a) R¹ represents t-butyl, R² represents H, and R³ represents phenyl,
b) R¹ represents methyl, R² represents H, and R³ represents carboxymethyl, or
c) R¹ represents H, R² represents H, and R³ represents 2-(4-methyl-oxa-3,3-diazole);

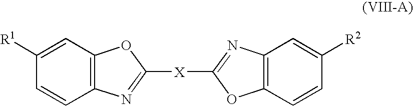

wherein
a) X represents 4,4′-stilbenediyl, and R¹ and R² each represent H,
b) X represents 2,5-thiophenediyl, and R¹ and R² each represent t-butyl,
c) X represents 1,4-naphthalenediyl, and R¹ and R² each represent H, or
d) X represents 1,1-ethenediyl, and R¹ and R² each represent methyl;

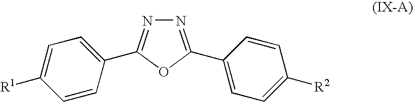

wherein R¹ and R² each represent diethylamino;

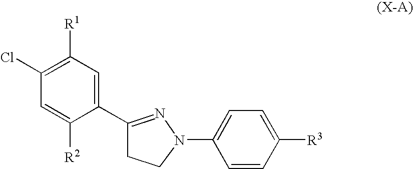

wherein
a) R¹ and R² each represent H, and R³ represents SO₂NH₂,
b) R¹ and R² each represent H, and

R³ represents SO₂CH₂CH₂OCH₂CH₂N(CH₃)₂,

c) R¹ and R² each represent H, and

R³ represents SO₂CH₂CH₂OCH(CH₃)CH₂N(CH₃)₂,

d) R¹ and R² each represent H, and R³ represents SO₂CH₃, or
e) R¹ and R² each represent H, and R³ represents SO₂CH₂CH₂OH;

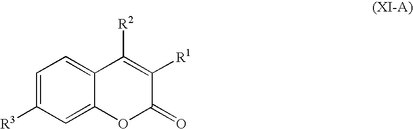

wherein
a) R¹ represents H, R² represents Me, and R³ represents diethylamino,
b) R¹ represents phenyl, R² represents H, and

R³ represents 2-N-naphthatriazolyl,

c) R¹ represents H, R² represents methyl, and R³ represents OH,
d) R¹ represents phenyl, R² represents H,

and R³ represents NH-(4,6-dichloro)-(1,3,5)-triazine, or

e) R¹ represents Ph, R² represents H, and

R³ represents 1-(3-methylpyrazolinyl);

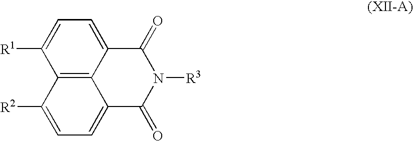

wherein
a) R¹ represents H, R² represents methoxy, and R³ represents methyl; or
b) R¹ and R² each represent OEt, and R³ represents methyl;

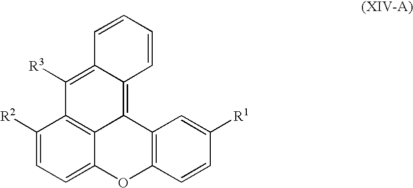

wherein
a) R¹ and R² each represent methyl, and R³ represents H, or
b) R¹ and R² each represent methyl, and R³ represents carboxymethyl;

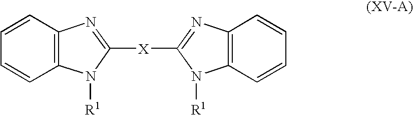

wherein
a) X represents 1,2-ethenediyl, and R¹ represents Me, or
b) X represents 4,4′-stilbenediyl, and R¹ represents methyl;

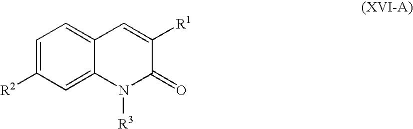

wherein R¹ represents Ph, R² represents diethylamino, and R³ represents ethyl; and

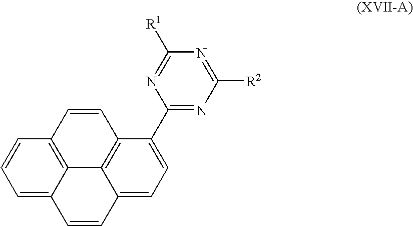

wherein R¹ and R² each represent methoxy.

From those sensitizers, the following compounds of formulae (IIIa) and/or (IVa) are particularly preferred:

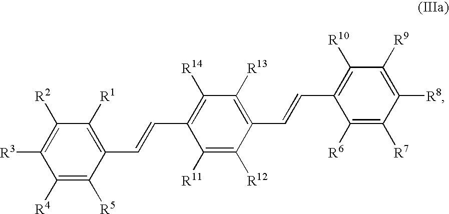

wherein
R¹ to R¹⁴ independently represent a hydrogen atom, an alkyl group, an alkoxy group, a cyano group, or a halogen atom, and at least one of R¹ to R¹⁰ represents an alkoxy group having more than 1 carbon atom;

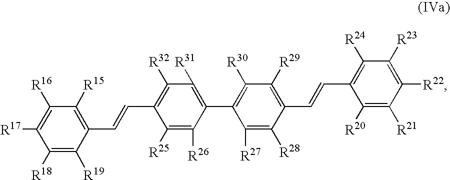

wherein
R¹ to R³ independently represent a hydrogen atom, an alkyl group, an alkoxy group, a cyano group, or a halogen atom, and at least one of R¹⁵ to R²⁴ represents an alkoxy group having more than 1 carbon atom. The alkyl and alkoxy groups can be optionally substituted and their substituent can be selected to adjust the solubility of the sensitizer and may be, for example, halogen, ester, ether, thioether, or hydroxy. The alkyl or alkoxy groups may be straight chain or cyclic, but a branched chain is preferred for the sensitizers of formulae (IIIa) and (IVa).

Particular advantages are achieved with sensitizers of formula (IIIa), wherein R¹, R⁵, R⁶, R¹⁰, R¹¹, R¹², R¹³, and R¹⁴ independently represent a hydrogen atom, a fluorine atom, or a chlorine atom, in particular R¹, R⁵, R⁶, and R¹⁰ being a hydrogen atom; R² to R⁴, R⁷ to R⁹ independently are alkoxy groups; and at least two of the alkoxy groups are branched and have from 3 to 15 carbon atoms. Especially preferred are sensitizers of formulae (IIIa) as disclosed above, wherein R², R⁴, R⁷, R⁹ independently represent a methoxy group and R³ and R⁸ independently are branched alkoxy groups having 3 to 15 carbon atoms.

Particular advantages are also achieved with sensitizers of formula (IVa), wherein R¹⁵, R¹⁹, R²⁰, R²⁴, R²⁵ to R³², independently represent a hydrogen atom, a fluorine atom or a chlorine atom, in particular R¹⁵, R¹⁹, R²⁰, R²⁴ being a hydrogen atom; R¹⁶ to R¹⁸, R²¹ to R²³, independently are alkoxy groups; and at least two of the alkoxy groups are branched and have from 3 to 15 carbon atoms. Especially preferred for the present invention are sensitizers of formulae (IVa) as disclosed above, wherein R¹⁶, R¹⁸, R²¹, R²³ independently represent a methoxy group and R¹⁷ and R²² independently are branched alkoxy groups having 3 to 15 carbon atoms.

The following structures are examples of preferred sensitizers of the present invention and their solubility S is given in brackets as g sensitizer/kg methyl ethyl ketone measured at 20° C.

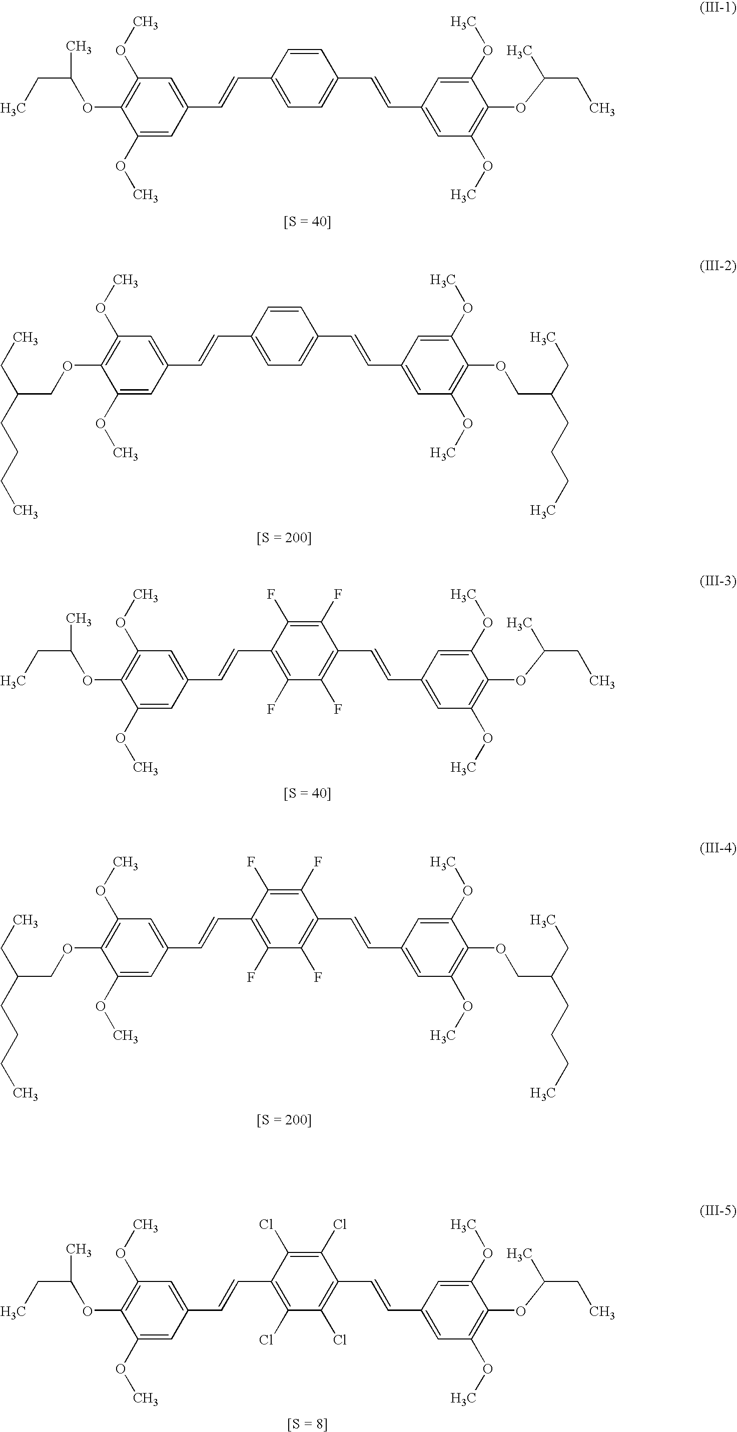

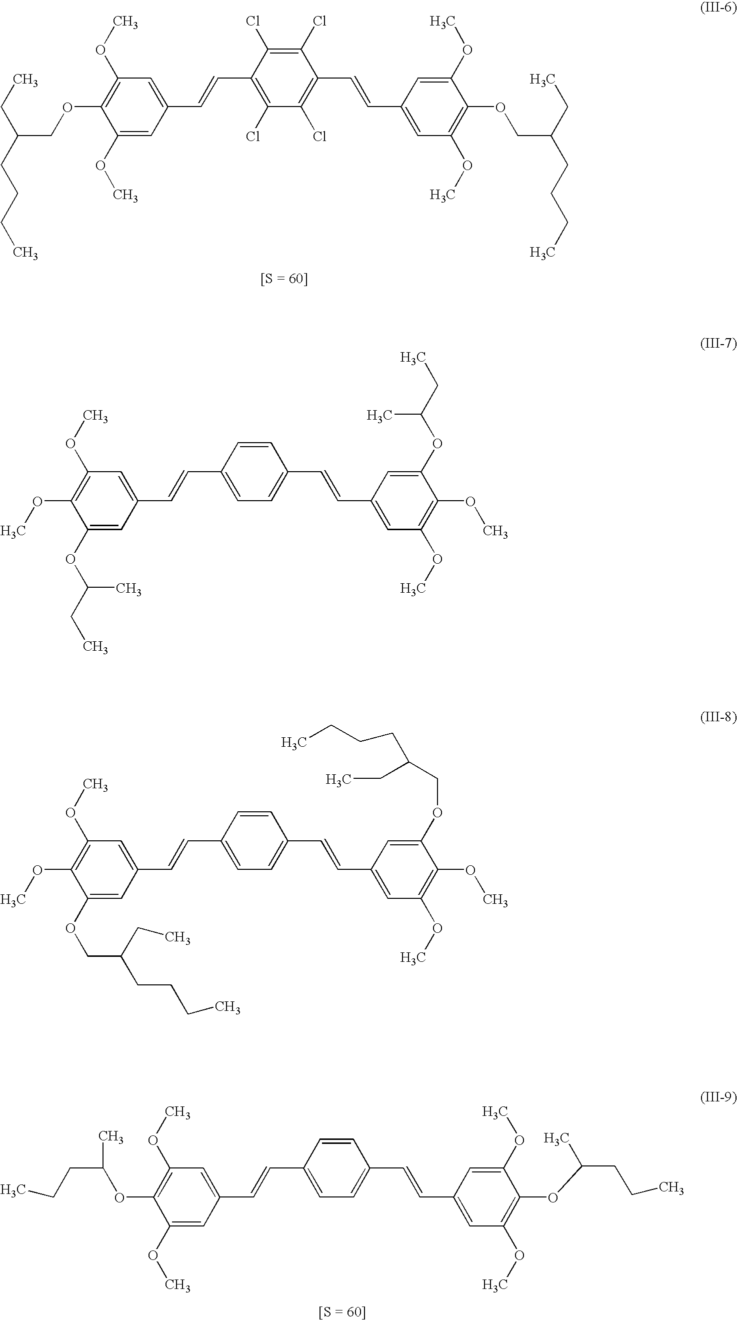

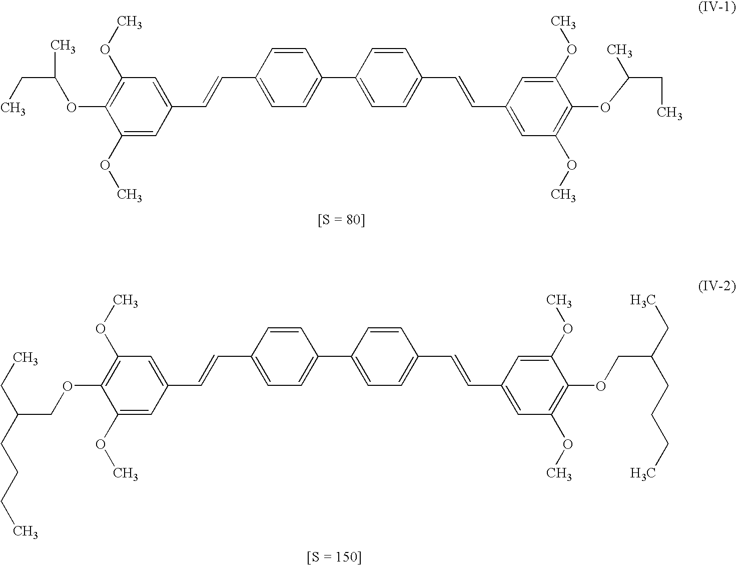

Most sensitizers useful for preferred embodiments of the present invention can be synthesized by known methods and the synthesis of the highly preferred sensitizers of formulae (IIIa) and (IVa) can be performed in analogy to the synthesis of sensitizer (III-1) as disclosed in the following.

### Synthesis of Intermediate (C-3)

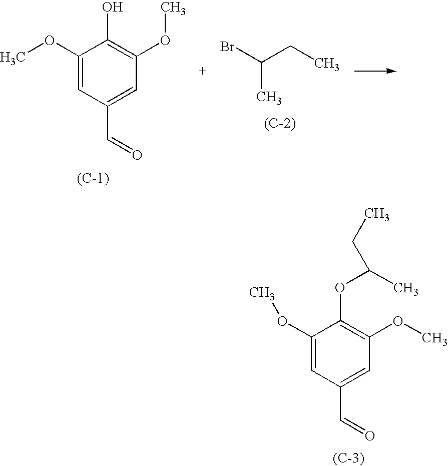

To a mixture of 8.365 kg (45.0 mol) syringaldehyde (C-1) and 1.494 kg (9.0 mol) potassium iodide is added 20.25 L sulfolane at room temperature. After heating up this mixture to 30° C. under nitrogen, 3.12 kg (47.25 mol) of KOH in water and 2.80 kg (20.25 mol) K₂CO₃ are added. After warming the reaction mixture to 75° C., 12.78 kg (90.0 mol) 2-bromo butane (C-2) is added over a period of 30 minutes. Heating at 75° C. is continued for 24 hours, followed by cooling to 25° C. Then 25 L water is added and the reaction product is extracted with 18 L methyl t-butyl ether (MTBE). The organic phase is consecutively a) two times washed with 6.0 L of a 7.5 wt. % K₂CO₃ solution in water respectively, b) two times washed with 13.5 L of pure water respectively and finally, c) two times washed with 4.5 kg of a 20 wt. % NaCl solution in water respectively. The solvent (MTBE) is removed by distillation under reduced pressure of 50 mBar at 75° C. and thereby are obtained 7.845 kg (theoretical yield of 75%) of the crude intermediate (C-3) as a yellow oil, that is used in the synthesis of (III-1) without further purification.

### Synthesis of Sensitizer (III-1)

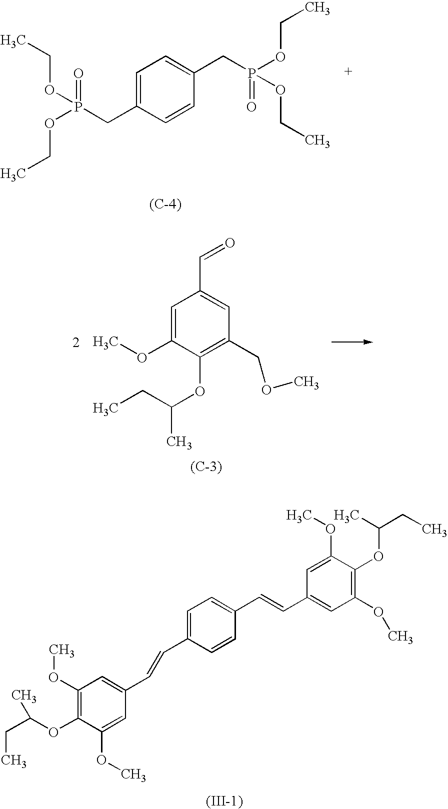

To a mixture of 9.63 kg (25.46 mol) p-xylylene-bis-phosphonate (C-4) and 12.13 kg (50.92 mol) of the crude intermediate (C-3) in 20 L THF, 4.70 kg (71.3 mol) of KOH is added at room temperature. After heating the stirred reaction mixture at reflux for 3.5 hours, the reaction product is precipitated by adding a mixture of 25.2 kg methanol and 9.9 kg water, followed by further cooling to 20° C. The crystalline product (III-1) is filtered off, washed with several portions of methanol/water on the filter and dried at 50° C. The yield is 9.05 kg (theoretical yield of 67%) of (III-1) having a melting point of 154° C.

A suitable synthesis for the p-xylylene-bis-phosphonate (C-4) is known from the literature, e.g., from B. P. Lugovkin and B. A. Arbuzov, Doklady Akademii Nauk SSSR (1948), 59, pages 1301 to 1304.

The photopolymerizable composition preferably includes a hexaarylbisimidazole (HABI; dimer of triaryl-imidazole) compound as a photopolymerization initiator (photoinitiator).

A procedure for the preparation of hexaarylbisimidazoles is described in DE 1470 154 and their use in photopolymerizable compositions is documented in EP 24 629, EP 107 792, U.S. Pat. No. 4,410,621, EP 215 453, and DE 3 211 312. Preferred derivatives are, e.g., 2,4,5,2′,4′,5′-hexaphenylbisimidazole, 2,2′-bis(2-chlorophenyl)-4,5,4′,5′-tetraphenylbisimidazole, 2,2′-bis(2-bromophenyl)-4,5,4′,5′-tetraphenylbisimidazole, 2,2′-bis(2,4-dichlorophenyl)-4,5,4′,5′-tetraphenylbisimidazole, 2,2′-bis(2-chlorophenyl)-4,5,4′,5′-tetrakis(3-methoxyphenyl)bisimidazole, 2,2′-bis(2-chlorophenyl)-4,5,4′,5′-tetrakis(3,4,5-trimethoxyphenyl)-bisimidazole, 2,5,2′,5′-tetrakis(2-chlorophenyl)-4,4′-bis(3,4-dimethoxyphenyl)bisimidazole, 2,2′-bis(2,6-dichlorophenyl)-4,5,4′,5′-tetraphenylbisimidazole, 2,2′-bis(2-nitrophenyl)-4,5,4′,5′-tetraphenylbisimidazole, 2,2′-di-o-tolyl-4,5,4′,5′-tetraphenylbisimidazole, 2,2′-bis(2-ethoxyphenyl)-4,5,4′,5′-tetraphenylbisimidazole, and 2,2′-bis(2,6-difluorophenyl)-4,5,4′,5′-tetraphenylbisimidazole. The amount of the HABI photoinitiator typically ranges from 0.01% to 30% by weight, preferably from 0.5% to 20% by weight, relative to the total weight of the non volatile components of the photopolymerizable composition.

Excellent results, in particular the highest sensitivity, can be obtained by the combination of an optical brightener as the sensitizer and a hexaarylbisimidazole as the photoinitiator, sensitizers of formulae (III) and (IV) being particularly preferred.

Hexaarylbisimidazole compounds can be used as photoinitiators either alone or in combination with further photoinitiators. Known photopolymerization initiators can be used in the composition in combination with hexarylbisimidazole compounds. Suitable classes include aromatic ketones, aromatic onium salts, organic peroxides, thio compounds, ketooxime ester compounds, borate compounds, azinium compounds, metallocene compounds, active ester compounds, and compounds having a carbon-halogen bond. Many specific examples of such photoinitiators can be found in EP-A 1091247.

Preferably, hexaarylbisimidazole compounds are used alone or in combination with aromatic ketones, aromatic onium salts, organic peroxides, thio compounds, ketoxime ester compounds, borate compounds, azinium compounds, active ester compounds, or compounds having a carbon halogen bond.

In a preferred embodiment of the present invention, the hexaarylbisimidazole compounds make more than 50 mol-%, preferably at least 80 mol-%, and particularly preferred at least 90 mol-% of all the photoinitiators used in the photopolymerizable composition.

The polymerizable compound can be selected from a wide series of photo-oxidizable compounds. Suitable compounds contain primary, secondary, and in particular tertiary amino groups. Radically polymerizable compounds containing at least one urethane and/or urea group and/or a tertiary amino group are particularly preferred. The term “urea group” is to be understood in the context of the present invention as a group of the formula >N—CO—N<, wherein the valences on the nitrogen atoms are saturated by hydrogen atoms and hydrocarbon radicals (with the proviso that not more than one valence on either of the two nitrogen atoms is saturated by one hydrogen atom). However, it is also possible for one valence on one nitrogen atom to be bonded to a carbamoyl (—CO—NH—) group, producing a biuret structure.

Also suitable are compounds containing a photo-oxidizable amino, urea or thio group, which may be also be a constituent of a heterocyclic ring. Compounds containing photo-oxidizable enol groups can also be used. Specific examples of photo-oxidizable groups are triethanolamino, triphenylamino, thiourea, imidazole, oxazole, thiazole, acetylacetonyl, N-phenylglycine, and ascorbic acid groups. Particularly suitable compounds are monomers containing photo-oxidizable groups corresponding to the following formula (PC-I):

R₍ₘ₋ₙ₎Q[(—CH₂—CR¹R²—O)ₐ—CO—NH—(X¹—NH—CO—O)_{b}—X²—(O—CO—CR³═CH₂)_{c}]ₙ (PC-I)

wherein
R represents an alkyl group having 2 to 8 carbon atoms ((C₂-C₈) alkyl group), a (C₂-C₈) hydroxyalkyl group, or a (C₆-C₁₄) aryl group,
Q represents

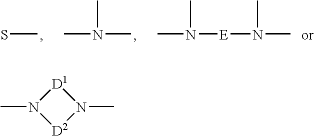

wherein
E represents a divalent saturated hydrocarbon group of 2 to 12 carbon atoms, a divalent 5- to 7-membered, saturated iso- or heterocyclic group, which may contain up to 2 nitrogen, oxygen and/or sulfur atoms in the ring, a divalent aromatic mono- or bicyclic isocyclic group of 6 to 12 carbon atoms, or a divalent 5- or 6-membered aromatic heterocyclic group; and
D¹ and D² independently represent a saturated hydrocarbon group of 1 to 5 carbon atoms,
R¹ and R² independently represent a hydrogen atom, an alkyl or alkoxyalkyl group,
R³ represents a hydrogen atom, a methyl or ethyl group,
X¹ represents a straight-chained or branched saturated hydrocarbon group of 1 to 12 carbon atoms,
X² represents a (c+1)-valent hydrocarbon group in which up to 5 methylene groups may have been replaced by oxygen atoms,
a is an integer from 0 to 4,
b is 0 or 1,
c is an integer from 1 to 3,
m is an integer from 2 to 4, and
n is an integer from 1 to m.

Compounds of this nature and processes for their preparation are described in EP 287 818. If a compound of general formula (PC-I) contains several radicals R or several radicals according to the structure indicated between square brackets, i.e., if (n−m)>1 and n>1, these radicals can be identical or different from one another. Compounds according to formula (PC-I), wherein n=m, are particularly preferred. In this case, all radicals contain polymerizable groups. Preferably, the index a is 1; if several radicals are present, the value of a cannot be 0 in more than one radical. If R is an alkyl or hydroxyalkyl group, R generally contains 2 to 6, particularly 2 to 4 carbon atoms. Aryl radicals R are in general mononuclear or binuclear, preferably mononuclear, and may be substituted with (C₁-C₅) alkyl or (C₁-C₅) alkoxy groups. If R¹ and R² are alkyl or alkoxy groups, they preferably contain 1 to 5 carbon atoms. R³ is preferably a hydrogen atom or a methyl group. X¹ is preferably a straight-chained or branched aliphatic and/or cycloaliphatic radical of preferably 4 to 10 carbon atoms. In a preferred embodiment, X² contains 2 to 15 carbon atoms and is in particular a saturated, straight-chained, or branched aliphatic and/or cycloaliphatic radical containing this amount of carbon atoms. Up to 5 methylene groups in these radicals may have been replaced by oxygen atoms; in the case of X² being composed of pure carbon chains, the radical generally has 2 to 12 carbon atoms, preferably 2 to 6 carbon atoms. X² can also be a cycloaliphatic group of 5 to 10 carbon atoms, in particular a cyclohexane diyl group. The saturated heterocyclic ring formed by D¹, D² and both nitrogen atoms generally has 5 to 10 ring members in particular 6 ring members. In the latter case the heterocyclic ring is preferably a piperazine and the radical derived therefrom a piperazine-1,4-diyl radical. In a preferred embodiment, radical E is an alkane diyl group which normally contains about 2 to 6 carbon atoms. Preferably the divalent 5- to 7-membered, saturated, isocyclic group E is a cyclohexane diyl group, in particular a cyclohexane-1,4-diyl group. The divalent, isocyclic, aromatic group E is preferably an ortho-, meta- or para-phenylene group. The divalent 5- or 6-membered aromatic heterocyclic group E, finally, contains preferably nitrogen and/or sulphur atoms in the heterocyclic ring. c is preferably 1, i.e., each radical in the square bracket generally contains only one polymerizable group, in particular only one (meth)acryloyloxy-group.

The compounds of formula (PC-I) wherein b=1, which accordingly contain two urethane groups in each of the radicals indicated in the square brackets, can be produced in a known way by conversion of acrylic esters or alkacrylic esters which contain free hydroxyl groups with equimolar amounts of diisocyanates. Excess isocyanate groups are then, for example, reacted with tris(hydroxyalkyl)amines, N,N′-bis(hydroxyalkyl)piperazines or N,N,N′,N′-tetrakis(hydroxyalkyl)alkylenediamines, in each of which individual hydroxyalkyl groups may have been replaced by alkyl or aryl groups R. If a=0, the result is a urea grouping. Examples of the hydroxyalkylamine starting materials are diethanolamine, triethanolamine, tris(2-hydroxypropyl)amine, tris(2-hydroxybutyl)amine, and alkyl-bis-hydroxyalkylamines. Examples of suitable diisocyanates are hexamethylene diisocyanate, 2,2,4-trimethylhexamethylene diisocyanate, 1,4-cyclohexylene diisocyanate (=1,4-diisocyanatocyclohexane), and 1,1,3-trimethyl-3-isocyanatomethyl-5-isocyanatocyclohexane. The hydroxy-containing esters used are preferably hydroxyethyl(meth)acrylate, hydroxypropyl(meth)acrylate and hydroxyisopropyl (meth)acrylate.

The polymerizable compounds of formula (PC-I) wherein b=0 are prepared converting the above-described hydroxyalkylamino compounds with isocyanate-containing acrylic or alkacrylic esters. A preferred isocyanate-containing ester is isocyanoto-ethyl(meth)acrylate.

Further polymerizable compounds including photooxidizable groups suitable for preferred embodiments of the present invention are compounds according to the following formula (PC-II):

R₍ₘ₋ₙ₎Q[(—CH₂—CRR—O)_{a′}-(CH₂—CH[CH₂—O—CO—CR³═CH₂]—O)_{b′}—H]ₙ (PC-II)

wherein a′ and b′ independently represent integers from 1 to 4 and Q, R¹, R², R³, n, and m have the same meaning as above and Q can also be a group of the formula >N-E′-N< wherein the radical E′ corresponds to the following formula (PC-III):

—CH₂—CH(OH)—CH₂—[O-(p)C₆H₄—C(CH₃)₂-(p)C₆H₄—CH₂—CH(OH)—CH₂—]_{c} (PC-III)

wherein c has the same meaning as in formula (I) and (p)C₆H₄ represents para-phenylene.

The compounds of formula (PC-II) can be prepared analogously to those of formula (PC-I), except that the conversion products of hydroxyalkyl acrylates or alkacrylates and diisocyanates are replaced by the corresponding acrylic and alkacrylic glycide esters. Compounds of formula (PC-III) and processes for their preparation are disclosed in EP 316 706.

Further useful polymerizable compounds containing photooxidizable groups are acrylic and alkacrylic esters of the following formula (PC-IV):

Q′[(—X^{1′}—CH₂—O)ₐ—CO—NH(—X¹—NH—CO—O)_{b}—X²—O—CO—CR³═CH₂]ₙ (PC-IV)

wherein
Q′ represents

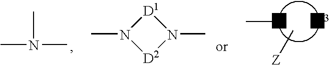

wherein D¹ and D² independently represent a saturated hydrocarbon group of 1 to 5 carbon atoms and D³ represents a saturated hydrocarbon group of 4 to 8 carbon atoms, which together with the nitrogen atom forms a 5- or 6-membered heterocyclic ring; X^{1′} represents —CᵢH₂ᵢ— or

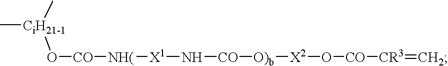

Z represents a hydrogen atom or a radical of the following formula:

—CₖH₂ₖ—O—CO—NH(—X¹—NH—CO—O)_{b}—X²—O—CO—CR³═CH₂;

i,k independently represent integers from 1 to 12;
n′ represents an integer from 1 to 3; and
a is 0 or 1; provided that a is 0 in at least one of the radicals bonded to Q;
X¹, R³, a, and b have the same meaning as given in the above formula (PC-I); and
X² represents a divalent hydrocarbon group in which up to 5 methylene groups may be replaced by oxygen atoms.

In formula (PC-IV), index a is preferably 0 or 1 and i preferably represents a number between 2 and 10. Preferred radicals Q are piperazine-1,4-diyl (D¹=D²═CH₂—CR₂), piperidine-1-yl (D³═(CH₂)₅, Z=H), and 2-(2-hydroxyethyl)-piperidine-1-yl (D³═(CH₂)₅, Z=CH₂CH₂OH).

Of the compounds of formula (PC-IV), those which apart from a urea group contain at least one urethane group are preferred. Here again, the term “urea group” is to be understood as the group of formula >N—CO—N<already mentioned above. Compounds of formula (PC-IV) and processes for their preparation are disclosed in EP 355 387.

Also suitable polymerizable compounds are reaction products of mono- or diisocyanates with multifunctional alcohols, in which the hydroxy groups are partly or completely esterified with (meth)acrylic acid. Preferred compounds are materials which are synthesized by the reaction of hydroxyalkyl-(meth)acrylates with diisocyanates. Such compounds are basically known and, for instance, described in DE 28 22 190 and DE 20 64 079.

The amount of polymerizable compound including photooxidizable groups generally ranges from 5% to 75% by weight, preferably from 10% to 65% by weight, relative to the total weight of the non volatile compounds of the photopolymerizable composition.

Moreover, the composition can contain polyfunctional (meth)acrylate or alkyl(meth)acrylate compounds as crosslinking agents. Such compounds contain more than 2, preferably between 3 and 6 (meth)acrylate and/or alkyl(meth)acrylate groups and include, in particular, (meth)acrylates of saturated aliphatic or alicyclic trivalent or polyvalent alcohols such as trimethylol ethane, trimethylol propane, pentaerythritol, or dipentaerythritol.

The total amount of polymerizable compounds generally ranges from about 10% to 90% by weight, preferably from about 20% to 80% by weight, relative to the total weight of the non volatile components of the photopolymerizable composition.

The following specific example is a preferred polymerizable compound:

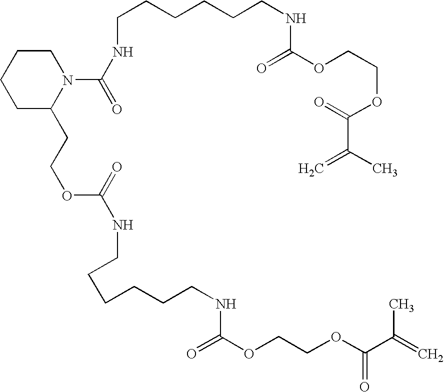

In order to achieve a high sensitivity, it is advantageous to add a radical chain transfer agent as described in EP 107 792 to the photopolymerizable composition. The preferred chain transfer agents are sulfur containing compounds, especially thiols like, e.g., 2-mercaptobenzothiazole, 2-mercaptobenzoxazole, or 2-mercapto-benzimidazole. The amount of chain transfer agent generally ranges from 0.01% to 10% by weight, preferably from 0.1% to 2% by weight, relative to the total weight of the non volatile components of the photopolymerizable composition.

Optionally pigments, e.g., pre-dispersed phthalocyanine pigments, can be added to the composition for coloring the composition and the layers produced therewith. Their amount generally ranges from about 1% to 20% by weight, preferably from 2% to 15% by weight and particularly preferred from about 2% to 10% by weight related to the total weight of the non volatile components of the composition. Particularly suitable pre-dispersed phthalocyanine pigments are disclosed in DE 199 15 717 and DE 199 33 139. Preference is given to metal-free phthalocyanine pigments.

In order to adjust the photopolymerizable composition to specific needs, thermal inhibitors or stabilizers for preventing thermal polymerization may be added. Furthermore additional hydrogen donors, dyes, colored or colorless pigments, color formers, indicators, and plasticizers may be present. These additives are conveniently selected so that they absorb as little as possible in the actinic range of the image-wise applied radiation.

The photopolymerizable composition is preferably applied to the support by processes which are known per se to the person skilled in the art. In general, the components of the photopolymerizable composition are dissolved or dispersed in an organic solvent or solvent mixture, the solution or dispersion is applied to the intended support by pouring on, spraying on, immersion, roll application or in a similar and the solvents are removed during the subsequent drying.

Known supports can be used for the photopolymer printing plate, like, e.g., foils, tapes, or plates made of metal or plastic and in the case of screen-printing also of Perlon gauze. Preferred metals are aluminum, aluminum alloys, steel, and zinc; aluminum and aluminum alloys being particularly preferred. Preferred plastics are polyester and cellulose acetates, polyethyleneterephthalate (PET) being particularly preferred.

In most cases, it is preferred to treat the surface of the support mechanically and/or chemically and/or electrochemically to optimally adjust the adherence between the support and the photosensitive coating and/or to reduce the reflection of the image-wise exposed radiation on the surface of the support (antihalation).

The most preferred support is made of aluminum or an aluminum alloy, wherein its surface is electrochemically roughened, thereafter anodized, and optionally treated with a hydrophilizing agent like, e.g., poly(vinylphosphonic acid).

In a preferred embodiment of the present invention, a protective layer (protective overcoat) is arranged on top of the photosensitive coating. Preferably, the protective layer has a dry coating weight of less than 3.0 g/m², in particular less than 2.5 g/m², and particularly preferred from more than 0.25 g/m² to less than 2.5 g/m².

The protective overcoat preferably includes at least one type of poly(vinyl alcohol), in particular a poly(vinyl alcohol) wherein the mean degree of saponification is less than 93 mol-%.

The degree of saponification is related to the production of poly(vinyl alcohols). As the monomer of poly(vinyl alcohol), vinyl alcohol, is nonexistent, only indirect methods are available for the production of poly(vinyl alcohol). The most important manufacturing process for poly(vinyl alcohol) is the polymerization of vinyl esters or ethers, with subsequent saponification or transesterification. The preferred starting material for the poly(vinyl alcohol) is a vinyl alcohol esterified by a mono carboxylic acid and in particular vinyl acetate, but derivatives of vinyl acetate, vinyl esters of dicarboxylic acids, vinyl ethers and the like can also be used. The degree of saponification as defined for the preferred embodiments of the present invention is the molar degree of hydrolysis irrespective of the process used for the hydrolysis. Pure poly(vinyl alcohol) has, e.g., a degree of saponification of 100 mol-%, but commercial products often have a degree of saponification of 98 mol-%. The poly(vinyl alcohols) as used for the preferred embodiments of the present invention contain mainly 1,3-diol units, but may also contain small amounts of 1,2-diol units. In the partially saponified poly(vinyl alcohols), the ester or the ether group can be distributed statistically or blockwise. Preferred partially saponified poly(vinyl alcohols) have a viscosity of a 4% aqueous solution at 20° C. of 4 mPa·s to 60 mPa·s, preferably of 4 mPa·s to 20 mPa·s, and in particular of 4 mPa·s to 10 mPa·s.

Preferred poly(vinyl alcohols) are commercially available, e.g., under the tradename Mowiol. Those products are characterized by two appended numbers, meaning the viscosity and the degree of saponification. For example, Mowiol 8-88 or Mowiol 8/88 mean a poly(vinyl alcohol) having as 4% aqueous solution at 20° C. a viscosity of ca 8 mPa·s and a degree of saponification of 88 mol-%. Although the use of only one type of poly(vinyl alcohol) is advantageous, it is preferred to use a mixture of two or more compounds because this allows a more accurate adjustment and a better optimization of further properties of the printing plate precursor. Preferably, poly(vinyl alcohols) differing in viscosity as defined above and/or in saponification degree are combined. Particularly preferred are a mixture of poly(vinyl alcohols) that differ in viscosity of their 4% aqueous solutions at 20° C. for at least 2 mPa·s or that differ in saponification degree for at least 5 mol-%. Most preferred are mixtures including at least 3 types of poly(vinyl alcohols), wherein at least two compounds differ in viscosity as defined above for at least 2 mPa·s and at least two compounds differ in saponification degree for at least 5 mol-%.

According to a preferred embodiment of the present invention, the overall mean saponification degree of all poly(vinyl alcohols) used in the protective layer is preferably less than 93 mol-%. In a particular preferred embodiment of the present invention, the overall mean saponification degree ranges from 71 mol-% to less than 93 mol-%, and in particular from 80 mol-% to 92.9 mol-%.

As long as the mean overall saponification limit of 93 mol-% is not reached, one of the poly(vinyl alcohols) used in a mixture can have a mean saponification degree of more than 93 mol-% and even up to 100 mol-%.

The overall mean saponification degree of the poly(vinyl alcohols) used in the protective overcoat of a printing plate precursor can be determined experimentally via ¹³C-NMR. To measure the ¹³C-NMR spectra, approximately 200 mg of the protective overcoat are dissolved in 1.0 ml DMSO and from this solution a 75 MHz ¹³C-NMR spectrum is taken, whose resonances can easily be interpreted and allow calculation of the degree of saponification. Such values are listed in Table 3 of the Examples as experimental values. A good correlation is obtained between the experimental values and the values known from the product specification of the poly(vinyl alcohols). The latter values are hereinafter called theoretical values of the mean saponification degree and can easily be calculated, when mixtures of poly(vinyl alcohols) are used.

Preferably, poly(vinyl alcohol)s are used in 50 to 99.9 weight percent (wt. %) relative to the total weight of the non-volatile compounds of the protective overcoat.

Apart from poly(vinyl alcohol)s, other water soluble polymers can be added to the layer such as poly(vinyl pyrrolidone), poly(ethylene oxide), gelatin, gum arabic, oxygen binding polymers with aliphatic amine groups known from EP 352 630 B1, methyl vinylether/maleic anhydride copolymers, poly(carboxylic acids), copolymers of ethylene oxide and poly(vinyl alcohol), carbon hydrates, hydroxy ethyl cellulose, acidic cellulose, cellulose, poly(arylic acid) and mixtures of these polymers.

Preferably, the poly(vinyl pyrrolidone) is only used in small quantities compared to the poly(vinyl alcohol). In a preferred embodiment of the present invention, poly(vinyl pyrrolidone) is used from 0 to 10 parts by weight of the poly(vinyl alcohol) used, from 0 to 3 parts by weight being particularly preferred. Most preferably, no poly(vinyl pyrrolidone) compounds are used.

In addition to the poly(vinyl alcohol) and the optional water soluble polymers disclosed above, known ingredients of protective layers can be used.

Examples of known ingredients suitable for the protective layer of the preferred embodiments of the present invention are surface wetting agents, coloring agents, complexants, polyethylenimines, and biocides.

The protective layer has to be transparent for actinic light. Preferably it is homogeneous, substantially impermeable to oxygen, water-permeable, and can be washed off preferably with conventional developer solutions used to form a printing relief after image-wise exposure of the photosensitive layer. The photosensitive layer is removed image-wise, whereas the protective layer is removable over the entire area of the element created. The wash-off of the protective layer can be done in a separate step, but can be done during the development step as well.

The dry coating weight of the protective overcoat can be measured by the following procedure. A plate is exposed for 4 hours to daylight. Next the plate is pre-heated between 104° C. and 127° C. (temperature measured via a thermostrip (THERMAX commercially available from TMC) at the back of the plate). The plate is cut to a size of 100 mm×100 mm and weighted on an analytical balance with 0.01 mg accuracy (=Weight A). Next, the protective overcoat is washed off with water (25° C.) for 2 minutes. Then the plate is rinsed with demineralized water and dried in an oven at 100° C. After drying the plate is allowed to cool down to room temperature, and the weight is determined using the same analytical balance as described earlier (=Weight B). The dry coating weight in g/m² of the protective overcoat is calculated using the formula below:

Dry coating weight (g/m²)=100×(Weight A−Weight B)

The protective layer can be coated on the photosensitive layer with known techniques and the coating solution preferably contains water or a mixture of water and an organic solvent. To allow a better wetting, the coating solution preferably contains, related to the solid content, up to 10 wt. %, and particularly preferred up to 5 wt. % of a surface active agent. Suitable representatives of surface active agents include anionic, cationic, and nonionic surface active agents like sodium alkylsulfates and -sulfonates having 12 to 18 carbon atoms, an example of which is sodium dodecylsulfate, N-cetyl- and C-cetyl betaine, alkylaminocarboxylate and -dicarboxylate, and polyethylene glycols with a mean molar weight up to 400.

In addition, further functions can be added to the protective layer. For example, it can be possible to improve the safelight suitability without decreasing the sensitivity of the layer by adding a coloring agent, e.g., a water-soluble dye, that has excellent transmission to the light having a wavelength of 300 nm to 450 nm and that absorbs light having a wavelength of 500 nm or more. This principle can easily be varied for different wavelengths to adjust the effective spectral sensitivity distribution of the printing plate precursor as needed.

A preferred embodiment of the present invention also relates to a method of making a lithographic printing plate including the steps of providing a photopolymer printing plate precursor as defined above, exposing the printing plate precursor, and processing the printing plate precursor in an aqueous alkaline developer.

In a preferred embodiment of the present invention, the exposure is done with a laser having an emission wavelength in the range from 300 nm to 1200 nm, in particular in the range from 300 nm to 600 nm, and particularly preferred in the range from 350 nm to 450 nm, and the exposure preferably is carried out at an energy density, measured on the surface of the plate, of 100 PJ/cm² or less.

Preferably, the processing of the printing plate precursor is done in the usual manner. After image-wise exposure, a pre-heat step can be performed to improve the cross-linking of the photosensitive layer, but preferably no pre-heat step is carried out. Then, the development step usually follows, wherein the optional overcoat layer and the unexposed portions of the photosensitive layer are removed. The removal (wash-off) of the overcoat layer and the development of the photosensitive layer can be done in two separate steps in this order, but can also be done in one step simultaneously. Preferably, the overcoat layer is washed-off with water before the development step. The wash-off can be done with cold water, but it is preferred to use hot water to accelerate the process. What remains on the support after the development step are the exposed and thereby photopolymerized portions of the photosensitive layer. The developer solution used for the development of the exposed printing plate precursors of the preferred embodiments of the present invention preferably is an aqueous alkaline solution having a pH of at least 11, a pH from 11.5 to 13.5 being particularly preferred. The developer solution can contain a small percentage, preferably less than 5 wt. %, of an organic, water-miscible solvent. To adjust the pH of the solution, an alkali hydroxide is preferably used.

Examples of preferred additional ingredients of the developer solution include, alone or in combination, alkali phosphates, alkali carbonates, alkali bicarbonates, an organic amine compound, alkali silicates, buffering agents, complexants, defoamers, surface active agents and dyes, but the suitable ingredients are not limited to the preferred examples and further ingredients can be used.

The method of development employed is not particularly limited, and may be conducted by soaking and shaking the plate in a developer, physically removing non-image portions while being dissolved in a developer by use of, e.g., a brush, or spraying a developer onto the plate so as to remove non-image portions. The time for development is selected depending upon the above method used so that the non-image portions can adequately by removed, and is optionally selected within a range of 5 seconds to 10 minutes.

After the development, the plate may be subjected to a hydrophilic treatment by, e.g., gum arabic optionally applied to the printing plate as the case requires (gumming step).

### EXAMPLES

A. Violet Sensitive Printing Plate Precursor

A composition was prepared (pw=parts per weight; wt. %=weight percentage) by mixing the components as specified in Table 1. A composition such as this was divided equally into portions of 24.61 g, and to each portion was added 1.608 g of a wt. % solution in 2-butanone of the binder according to Table 2. The resulting composition was coated on an electrochemically roughened and anodically oxidized aluminum sheet, the surface of which had been rendered hydrophilic by treatment with an aqueous solution of polyvinyl phosphonic acid (oxide weight 3 g/m²) and was dried for 1 minute at 120° C. (circulation oven). The resulting thickness of the layer was 1.5 g/m².

TABLE 1

| | Parts per |
|---|---|
| Component | weight (g) |
| A solution containing 88.2 wt. % of a reaction | 14.538 |
| product from 1 mole of 2,2,4-trimethyl- | |
| hexamethylenediisocyanate and 2 moles of hydroxy- | |
| ethylmethacrylate (viscosity 3.30 mm²/s at 25° C.) | |
| Heliogene blue D 7490 ® dispersion (9.9 wt. %, | 17.900 |
| viscosity 7.0 mm²/s at 25° C.), trade name of BASF AG | |
| 2,2′-bis(2-chlorophenyl)-4,4′,5,5′-tetraphenyl-1,2- | 1.448 |
| bisimidazole | |
| 1,4-di[3,5-dimethoxy-4-(1- | 0.958 |
| methylpropoxy)styryl]benzene (III-1) | |
| Edaplan LA 411 ® (1% in Dowanol PM ®, trade mark of | 2.250 |
| Dow Chemical Company) | |
| MET (mercaptobenzthiazole) | 0.068 |
| 2-butanone | 78.538 |
| propyleneglycol-monomethylether (Dowanol PM ®, trade | 130.358 |
| mark of Dow Chemical Company) | |

TABLE 2

| | | | Ratio | |
|---|---|---|---|---|
| | | Weight | (meth)acrylate: | Tg ° C. |
| | | average | (meth)acrylic | (measured |
| Exp. | Type of Binder | Mw (GPC) | acid (1H NMR) | by DSC) |
| 1 | Poly(methylmethacrylate- | 27386 | 82:18 | 127.8 |
| | co-methacrylic | | | |
| | acid) | | | |
| 2 | Poly(methylacrylate- | 15205 | 87:13 | 24.0 |
| | co-acrylic acid) | | | |
| 3 | Poly(n- | 50928 | 81:19 | 32.1 |
| | butylmethacrylate-co- | | | |
| | acrylic acid) | | | |
| 4 | Poly(n- | 65123 | 77:23 | 67.3 |
| | butylmethacrylate-co- | | | |
| | methacrylic acid) | | | |
| 5 | Poly (benzylacrylate- | 15571 | 89:11 | −7.5 |
| | co-acrylic acid) | | | |
| 6 | Poly(benzylacrylate- | 18412 | 86:14 | 12.9 |
| | co-methacrylic acid) | | | |

On top of the photosensitive layer, a solution in water with the composition as defined in Table 3 was coated and was dried at 110° C. for 2 minutes.

TABLE 3

| | Parts by |
|---|---|
| Component | Weight (g) |
| partially hydrolyzed polyvinylalcohol (degree of | 17.03 |
| hydrolysis 88%, viscosity 4 mPa · s in a solution | |
| of 4 wt. % at 20° C.). | |
| partially hydrolyzed polyvinylalcohol (degree of | 7.43 |
| hydrolysis 88%, viscosity 8 mPa · s in a solution | |
| of 4 wt. % at 20° C.). | |
| fully hydrolyzed polyvinylalcohol (degree of | 14.87 |
| hydrolysis 98%, viscosity 6 mPa · s in a solution | |
| of 4 wt. % at 20° C.). | |
| CA 24 E | 0.26 |
| Metolat FC 355 | 0.38 |
| Lutensol A8 (90%) | 0.032 |
| Water | 960 |

The so-formed protective overcoat had a dry thickness of 2.0 g/m².

The imaging was carried out with a Polaris violet platesetter device (flat bed system) equipped with a violet laser diode emitting between 392 nm and 417 nm. The following imaging conditions were used:
Scanning speed: 600 m/sec or 1000 m/sec
Variable image plane power: 0 mW to 25 mW
Spot diameter: 20 μm
Addressability: 1270 dpi

After imaging, the plate was processed in an Agfa VSP85 processor at a speed of 1.2 m/min. Before the processing, the plate was optionally heated by passing through the pre-heat section of the processor at 110° C. (pre-heat step), next the protective overcoat was washed off and the photolayer was processed in a water based alkaline developer (Agfa PD91) at 28° C. After a water rinsing and gumming step, the printing plate was ready. A 13-step exposure wedge with density increments of 0.15 was used to determine sensitivity of the plate.

The results of the exposure tests are shown in Table 4 as the sum of the density of the UGRA step wedges measured by a Gretag Macbeth D19C densitometer (cyan setting). One fully hardened step=1.00. Higher values indicate higher sensitivity of the plate.

TABLE 4

| | Laser | | UGRA sum. | |
|---|---|---|---|---|
| | energy | UGRA sum. | With Pre- | |
| Binder | (μJ/cm²) | No Pre-heat | heat | |
| 1 | 86 | No image | 3.66 | Comparison |
| 1 | 192 | 0 | / | Comparison |
| 2 | 86 | 1.57 | 3.79 | Invention |
| 2 | 192 | 3.49 | / | Invention |
| 3 | 86 | 1.12 | 1.76 | Invention |
| 3 | 192 | 3.62 | / | Invention |
| 4 | 86 | 0.87 | 2.77 | Invention |
| 4 | 192 | 5.58 | / | Invention |
| 5 | 86 | 2.01 | 3.17 | Invention |
| 5 | 192 | 4.31 | / | Invention |
| 6 | 86 | 2.18 | 3.54 | Invention |
| 6 | 192 | 4.48 | / | Invention |

It can be clearly seen that binders with a Tg below 70° C. give rise to the formation of a good image without the need for a pre-heat step. The image is even stronger when a higher laser energy is used.

B. IR Sensitive (Thermal) Printing Plate Precursor

A composition was prepared (pw=parts per weight; wt. %=weight percentage) by mixing the components as specified in Table 5. A composition such as this was divided into two portions of 78.84 g, and to each portion was added 8.61 g of a 33.0 wt. % solution in methylethyl ketone of the binder according to Table 2. The resulting composition was coated on an electrochemically roughened and anodically oxidized aluminum sheet, the surface of which has been rendered hydrophilic by treatment with an aqueous solution of polyvinyl phosphonic acid (oxide weight 3 g/m²) and was dried for 1 minute at 120° C. (circulation oven). The resulting thickness of the layer was 1.5 g/m².

TABLE 5

| | Parts per |
|---|---|
| | weight |
| Component | (g) |
| a solution containing 88.2 wt. % of a reaction | 7.44 |
| product from 1 mole of 2,2,4-trimethyl- | |
| hexamethylenediisocyanate and 2 moles of hydroxy- | |
| ethylmethacrylate (viscosity 3.30 mm²/s at 25° C.) | |
| Heliogene blue D 7490 ® dispersion (9.9 wt. %, | 15.35 |
| viscosity 7.0 mm²/s at 25° C.), trade name of BASF AG | |
| 2-[1,1′-biphenyl]-4-yl-4,6-bis(trichloromethyl)- | 0.891 |
| 1,3,5-triazine | |
| Infrared Absorber IR-1 | 0.357 |
| Edaplan LA 411 ® (10% in Dowanol PM ®, trade mark of | 0.149 |
| Dow Chemical Company) | |
| 2-butanone | 43.50 |
| propyleneglycol-monomethylether (Dowanol PM ®, trade | 89.99 |
| mark of Dow Chemical Company) | |

On top of the photosensitive layer, a solution in water with the composition as defined in Table 3 was coated and was dried at 110° C. for 2 minutes.

The so-formed protective overcoat had a dry thickness of 2.0 g/m².

The imaging was carried out with a Creo X36 platesetter equipped with an IR laser diode emitting at 830 nm. The energy received by the plate was varied between 35 mJ/cm² and 200 mJ/cm² and the sensitivity of the plate was defined by the energy at which 53% solid density was obtained on a 50% screen.

After imaging, the plate was processed in an Agfa processor at a speed of 1.2 m/min. Before the processing, the plate was optionally heated by passing through the pre-heat section of the processor at 110° C. (pre-heat step), next the protective overcoat was washed off and the photolayer was processed in a water based alkaline developer (Agfa PD91) at 28° C. After a water rinsing and gumming step, the printing plate was ready.

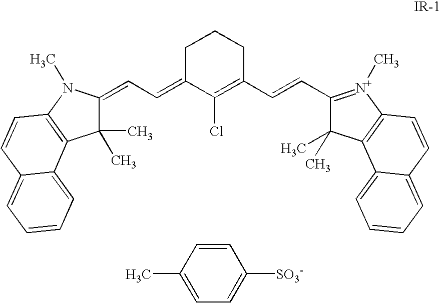

The results are shown in Table 6 and the sensitivities were measured by the energy at which 53% solid density was achieved on a 50% screen.

TABLE 6

| | Sensitivity | Sensitivity | |
|---|---|---|---|
| | (mJ/cm²) | (mJ/cm²) | |
| Binder | No pre-heat | With pre-heat. | |
| 1 | No image | 46 | Comparison |
| 2 | 145 | 45 | Invention |

The results clearly show an improvement in sensitivity when the low Tg binder is used relative to the standard binder 1.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-21. (canceled)

22: A photopolymer printing plate precursor comprising:
a photosensitive coating on a support; wherein
the photosensitive coating includes a composition that is photopolymerizable upon absorption of light having a wavelength between 300 nm and 600 nm;
the composition includes at least one binder, a polymerizable compound, a sensitizer, and a hexaarylbisimidazole compound as a photoinitiator; and
the binder is a copolymer that has a Tg of less than 70° C., and 1 mol-% to 50 mol-% of the monomeric units of the copolymer contain at least one acidic group.

23: A photopolymer printing plate precursor comprising:
a photosensitive coating on a support; wherein
the photosensitive coating includes a composition that is photopolymerizable upon absorption of light having a wavelength between 600 nm and 1200 nm;
the composition includes at least one binder, a polymerizable compound, and a photoinitiator; and
the binder is a copolymer that has a Tg of less than 70° C., and 1 mol-% to 50 mol-% of the monomeric units of the copolymer contain at least one acidic group.

24: A photopolymer printing plate precursor according to claim 22, wherein the acidic group is selected from a carboxylic acid group (—COOH), a carboxylic anhydride group (—(CO)O(CO)—), a sulfo group (—SO₃H), an imido group (HN═), a phosphono group (—PO(OH)₂), a N-acyl sulfonamido group (—SO₂NH—COR), or a phenolic hydroxy group (-phenyl-OH).

25: A photopolymer printing plate precursor according to claim 23, wherein the acidic group is selected from a carboxylic acid group (—COOH), a carboxylic anhydride group (—(CO)O(CO)—), a sulfo group (—SO₃H), an imido group (HN═), a phosphono group (—PO(OH)₂), a N-acyl sulfonamido group (—SO₂NH—COR), or a phenolic hydroxy group (-phenyl-OH).

26: A photopolymer printing plate precursor according to claim 22, wherein the binder has a Tg of less than 50° C.

27: A photopolymer printing plate precursor according to claim 23, wherein the binder has a Tg of less than 50° C.

28: A photopolymer printing plate precursor according to claim 24, wherein the binder has a Tg of less than 50° C.

29: A photopolymer printing plate precursor according to claim 25, wherein the binder has a Tg of less than 50° C.

30: A photopolymer printing plate precursor according to claim 22, wherein the binder has a Tg of less than 30° C.

31: A photopolymer printing plate precursor according to claim 23, wherein the binder has a Tg of less than 30° C.

32: A photopolymer printing plate precursor according to claim 24, wherein the binder has a Tg of less than 30° C.

33: A photopolymer printing plate precursor according to claim 25, wherein the binder has a Tg of less than 30° C.

34: A photopolymer printing plate precursor according to claim 22, further comprising a protective layer on top of the photosensitive coating.

35: A photopolymer printing plate precursor according to claim 23, further comprising a protective layer on top of the photosensitive coating.

36: A photopolymer printing plate precursor according to claim 34, wherein the protective layer has a dry coating weight from more than 0.25 g/m² to less than 2.5 g/m².

37: A photopolymer printing plate precursor according to claim 35, wherein the protective layer has a dry coating weight from more than 0.25 g/m² to less than 2.5 g/m².

38: A photopolymer printing plate precursor according to claim 22, wherein the binder is a copolymer containing monomeric units of an α,β-unsaturated carboxylic acid and/or an α,β-unsaturated dicarboxylic acid.

39: A photopolymer printing plate precursor according to claim 23, wherein the binder is a copolymer containing monomeric units of an α,β-unsaturated carboxylic acid and/or an α,β-unsaturated dicarboxylic acid.

40: A photopolymer printing plate precursor according to claim 22, wherein the sensitizer is an optical brightening agent.

41: A photopolymer printing plate precursor according to claim 22, wherein the sensitizer has a structure according to one of the following formulae: 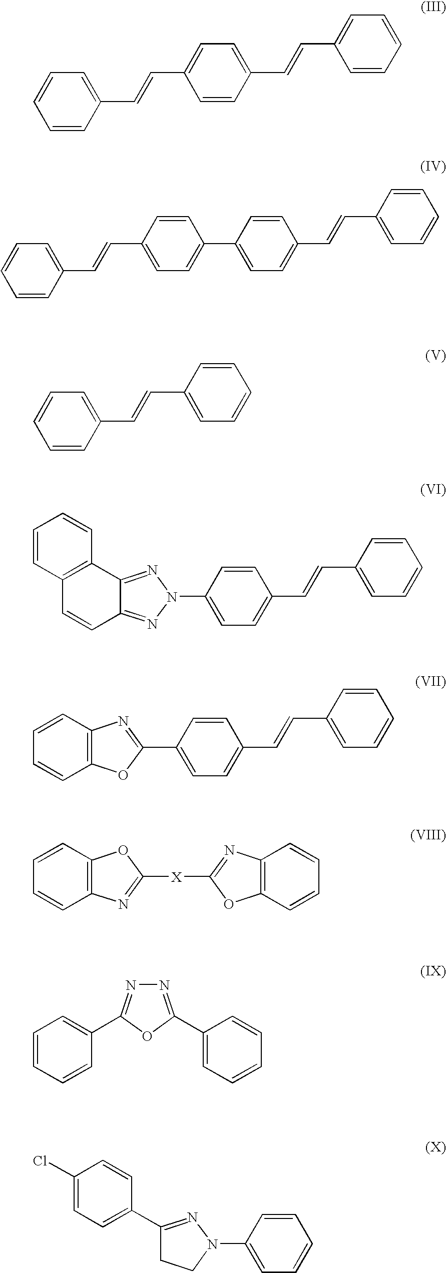 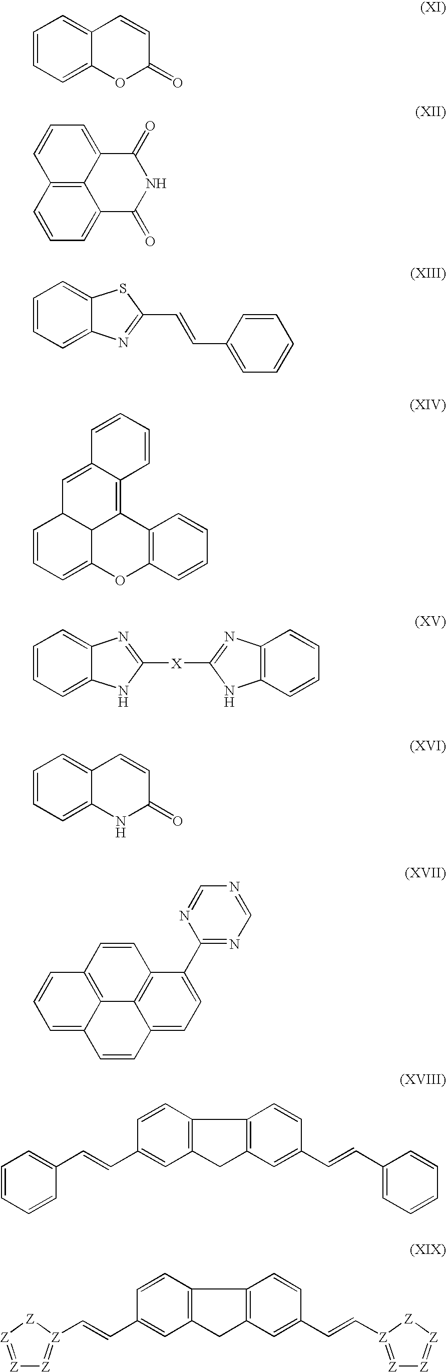
wherein Z mutually independently means non-hydrogen, non-metallic atoms;
wherein X is one of the following groups, * denoting the position of attachment in the above formulae: 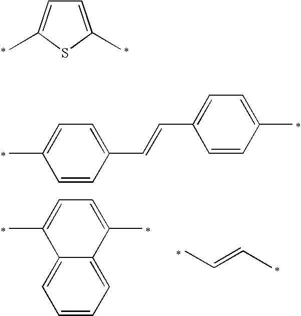
and wherein one or more of the nuclei in each of the above formulae (III) to (XIX) may be independently substituted by one or more groups selected from alkyl, alkoxy, alkylcarbonyl, alkoxycarbonyl, acyloxy, carboxyl, nitrile, amino, hydroxyl, alkylsulfonyl, and aminosulfonyl.

42: A method of making a lithographic printing plate comprising the steps of:
providing a photopolymer printing plate precursor as defined in claim 22;
exposing the printing plate precursor with a laser having an emission wavelength in the range from 300 nm to 600 nm; and
processing the printing plate precursor in an aqueous alkaline developer.

43: A method of making a lithographic printing plate comprising the steps of:
providing a photopolymer printing plate precursor as defined in claim 23;
exposing the printing plate precursor with a laser having an emission wavelength in the range from 600 nm to 1200 nm; and
processing the printing plate precursor in an aqueous alkaline developer.

44: A method according to claim 42, wherein no pre-heat step is carried out.

45: A method according to claim 43, wherein no pre-heat step is carried out.
